(19) United States
(12) Patent Application Publication
(10) Pub. No.: US 2025/0221293 A1
(43) Pub. Date: Jul. 3, 2025

(54) COMPOSITE MATERIAL AND PREPARATION METHOD THEREOF, AND LIGHT-EMITTING DEVICE

(71) Applicant: TCL Technology Group Corporation, Huizhou (CN)

(72) Inventor: Siyu XIA, Huizhou (CN)

(73) Assignee: TCL Technology Group Corporation, Huizhou (CN)

(21) Appl. No.: 19/002,644

(22) Filed: Dec. 26, 2024

(30) Foreign Application Priority Data
Dec. 27, 2023 (CN) 202311824112.4

(51) Int. Cl. H10K 85/10; C08G 73/02; C09C 1/04; C09C 3/10; H10K 50/15; H10K 50/165; H10K 102/00

(52) U.S. Cl. CPC H10K 85/111; C08G 73/0273; C09C 1/043; C09C 3/10; C01P 2004/64; H10K 50/15; H10K 50/165; H10K 2102/351

(57) ABSTRACT

The present disclosure provides a composite material and a preparation method thereof, and a light-emitting device. The composite material includes inorganic nanoparticles and a polymer, the polymer is attached to the inorganic nanoparticles, and the polymer contains a porphyrin group. Since the polymer has the property of isolating water and oxygen, when the polymer is attached to the inorganic nanoparticle, the influence of external water and oxygen on the inorganic nanoparticle may be weakened or eliminated, so that the electrical properties of the inorganic nanoparticle remain stable. Since the porphyrin group in the polymer has conductive properties, the electron transport efficiency of the composite material may be improved.

This application claims priority to Chinese Application No. 202311824112.4, entitled “COMPOSITE MATERIAL AND PREPARATION METHOD THEREOF, LIGHT-EMITTING DEVICE AND DISPLAY DEVICE”, filed on Dec. 27, 2023. The entire disclosures of the above application are incorporated herein by reference.

### TECHNICAL FIELD

The present disclosure relates to a technical field of light-emitting devices, and in particular, to a composite material and a preparation method thereof, and a light-emitting device.

### BACKGROUND

Electroluminescent devices include OLED (Organic Light-Emitting Diode) and QLED (Quantum Dot light-emitting Diode). QLED has the advantages of high color saturation, wettable preparation and high stability, which makes the research of QLED attract more and more attention. OLED has been widely used in display, lighting, smart wearable and other fields due to its good self-luminous characteristics, high contrast, fast response and flexible display.

An electroluminescent device usually includes a film layer such as a cathode, an electron transport layer, a light-emitting layer, and an anode, and because the electron transport performance of the existing electron transport layer is poor, the amount of electrons injected into the light-emitting layer is small, which leads to the problem of carrier imbalance in the light-emitting layer, and the electrical performance of the electroluminescent device is poor.

### Technical Solution

In view of this, embodiments of the present disclosure provide a composite material and a preparation method thereof, and a light-emitting device.

In a first aspect, embodiments of the present disclosure provide a composite material including inorganic nanoparticles and a polymer. The polymer is attached to the inorganic nanoparticles, and the polymer contains a porphyrin group.

In some embodiments, the polymer is a porphyrin-based conjugated microporous polymer.

In some embodiments, the porphyrin-based conjugated microporous polymer includes repeating units, each of the repeating units having a structure represented by formula (I):

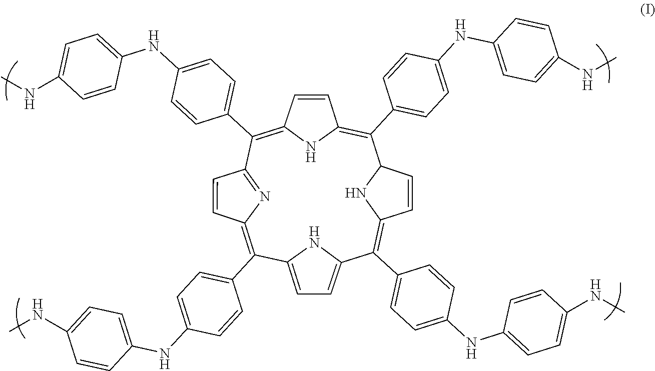

in the porphyrin-based conjugated microporous polymer, a number of the repeating units represented by the formula (I) is n, n ranges from 2 to 10.

In some embodiments, the polymer includes multiple micropores, each with a pore size ranging from 0.01 nm to 2 nm, and a total volume of the micropores accounts for 15% to 40% of a volume of the polymer.

In some embodiments, the inorganic nanoparticle is selected from one or more of a metal oxide, a doped metal oxide, a Group II-VI semiconductor material, a Group III-V semiconductor material and a Group I-III-VI semiconductor material;
the metal oxide is selected from one or more of ZnO, BaO, TiO₂, and SnO₂;
a metal oxide of the doped metal oxide is selected from one or more of ZnO, TiO₂, and SnO₂, and a doping element of the doped metal oxide is selected from one or more of Al, Mg, Li, In, and Ga;
the Group II-VI semiconductor material is selected from one or more of ZnS, ZnSe, and CdS;
the Group III-V semiconductor material is selected from one or more of InP and GaP; and
the Group I-III-VI semiconductor material is selected from one or more of CuInS and CuGaS.

In some embodiments, a mass ratio of the polymer to the inorganic nanoparticle is (1-5): 20.

In some embodiments, the composite material further includes a surfactant, the surfactant being distributed at least on the outer surface of the inorganic nanoparticles, and a molar ratio of the surfactant to the inorganic nanoparticles is 1:(2-8).

In a second aspect, embodiments of the present disclosure provide a method of preparing a composite material, including:
providing a polymer dispersion solution and an inorganic nanoparticle dispersion solution; wherein the polymer dispersion solution includes a first solvent and a polymer dispersed in the first solvent, the polymer containing a porphyrin group therein; and the inorganic nanoparticle dispersion solution includes a second solvent and inorganic nanoparticles dispersed in the second solvent;
mixing the polymer dispersion solution and the inorganic nanoparticle dispersion solution to obtain a composite material dispersion solution; and
performing solid-liquid separation on the composite material dispersion solution to obtain a composite material, wherein the composite material includes a polymer and a plurality of inorganic nanoparticles uniformly dispersed inside the polymer.

In some embodiments, a mass ratio of the polymer to the inorganic nanoparticles in the composite material dispersion solution is (1˜5): 20;
the step of mixing the polymer dispersion solution and the inorganic nanoparticle dispersion solution includes: mixing the polymer dispersion solution and the inorganic nanoparticle dispersion solution at a temperature of 3° C. to 10° C., and stirring for 5 hours to 10 hours after mixing.

In some embodiments, the inorganic nanoparticle dispersion solution further includes a surfactant, and a molar ratio of the surfactant to the inorganic nanoparticles is 1:(2-8).

In some embodiments, the step of providing the polymer dispersion solution includes: providing the polymer and dissolving the polymer in the first solvent to obtain the polymer dispersion solution.

In some embodiments, the polymer is a porphyrin-based conjugated microporous polymer, and the step of providing the polymer includes: mixing meso-tetra(p-bromophenyl)porphine, p-phenylenediamine, sodium tert-butoxide, 2-(dicyclohexylphosphino)-2,4,6-triisopropylbiphenyl, a catalyst and a third solvent, and reacting at a temperature of 100° C. to 120° C. for 40 hours to 56 hours to obtain the porphyrin-based conjugated microporous polymer. A molar ratio of meso-tetra(p-bromophenyl)porphine, p-phenylenediamine, sodium tert-butoxide, 2-(dicyclohexylphosphino)-2,4,6-triisopropylbiphenyl and the catalyst is 1:(2-5):(4-6):(0.1-0.14):(0.06-0.1).

In some embodiments, the step of providing the inorganic nanoparticle dispersion solution includes providing the inorganic nanoparticles and dissolving the inorganic nanoparticles in the second solvent to obtain the inorganic nanoparticle dispersion solution.

In some embodiments, the inorganic nanoparticles are zinc oxide nanoparticles, and the step of providing the inorganic nanoparticles includes: mixing a precipitant solution and a zinc salt solution, and reacting at a temperature condition of 50° C. to 70° C. for 2 hours to 3 hours to obtain the zinc oxide nanoparticles. A molar ratio of a precipitant to a zinc salt is (1-2): 6.

In a third aspect, embodiments of the present disclosure provide a light-emitting device including a first electrode, a second electrode, an electron transport layer and a light-emitting layer. The first electrode and the second electrode are disposed opposite each other, and the electron transport layer and the light-emitting layer are disposed between the first electrode and the second electrode. A material of the electron transport layer is a composite material, the composite material includes inorganic nanoparticles and a polymer attached to the inorganic nanoparticles, and the polymer contains a porphyrin group.

In some embodiments, the polymer is a porphyrin-based conjugated microporous polymer, and the porphyrin-based conjugated microporous polymer includes repeating units, each of the repeating units having a structure represented by formula (I):

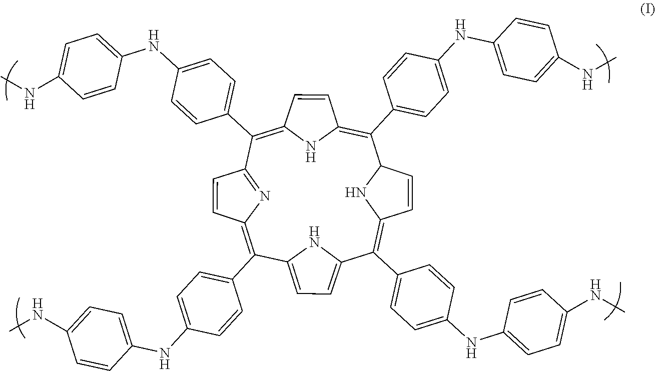

in the porphyrin-based conjugated microporous polymer a number of the repeating units represented by the formula (I) is n, n ranges from 2 to 10.

In some embodiments, the light-emitting device further includes a hole transport layer and a hole injection layer. The first electrode is an anode, and the second electrode is a cathode. The light-emitting layer, the hole transport layer, and the hole injection layer are disposed between the electron transport layer and the first electrode, and the light-emitting layer, the hole transport layer, and the hole injection layer are stacked in this order in a direction from the electron transport layer to the first electrode.

In some embodiments, the light-emitting device further includes the hole transport layer and the hole injection layer. The first electrode is the cathode, and the second electrode is the anode. The light-emitting layer, the hole transport layer, and the hole injection layer are disposed between the electron transport layer and the second electrode, and the light-emitting layer, the hole transport layer, and the hole injection layer are stacked in this order in a direction from the electron transport layer to the second electrode.

In some embodiments, a material of the hole transport layer includes one or more of 4,4′-N,N′-dicarbazolyl-biphenyl, poly[bis(4-phenyl)(2,4,6-trimethylphenyl)amine], N,N′-diphenyl-N,N′-bis(1-naphthyl)-1,1′-biphenyl-4,4″-diamine, N,N′-diphenyl-N,N′-bis(3-methylphenyl)-(1,1′-biphenyl)-4,4′-diamine, poly(N,N′-bis(4-butylphenyl)-N,N′-bis(phenyl)benzidine), N,N′-bis(4-(N,N′-diphenyl-amino)phenyl)-N,N′-diphenylbenzidine, 4,4′,4′-tris(N-carbazolyl)-triphenylamine, 4,4′,4′-tris(N-3-methylphenyl-N-phenylamino)triphenylamine, poly[(9,9′-dioctylfluorene-2,7-diyl)-co-(4,4′-(N-(4-sec-butylphenyl)diphenylamine))], poly(N-vinylcarbazole) and its derivatives, N,N′-bis(1-naphthyl)-N,N′-diphenyl-1,1′-biphenyl-4-4′-diamine, poly(phenylenevinylene), poly[2-methoxy-5-(2-ethylhexyloxy)-1,4-phenylenevinylene], poly[2-methoxy-5-(3′,7′-dimethyloctyloxy)-1,4-phenylenevinylene], 2,2′,7,7′-tetrakis[N,N-bis(4-methoxyphenyl)amino]-9,9′-spirobifluorene, 4,4′-cyclohexylbis[N,N-bis(4-methylphenyl)aniline], 1,3-bis(carbazol-9-yl)benzene, polyaniline, polypyrrole, poly(p-phenylenevinylene), aromatic tertiary amines, polynuclear aromatic tertiary amines, 4,4′-bis(p-carbazol-9-yl)-1,1′-biphenyl compounds, N,N,N′,N′-tetraarylbenzidine, poly(3,4-ethylenedioxythiophene)-polystyrene sulfonic acid and its derivatives, polymethacrylate and its derivatives, poly(9,9-octylfluorene) and its derivatives, polyspirofluorene and its derivatives, polythiophene and its derivatives;
a material of the hole injection layer includes one or more of poly(3,4-ethylenedioxythiophene)-polystyrenesulfonic acid and its derivatives, copper phthalocyanine, dipyrazino[2,3-f:2′,3′-h]quinoxaline-2,3,6,7,10,11-hexacarbonitrile, polydioxyethyl thiophene, 4,4′,4″-tris(N-3-methylphenyl-N-phenylamino)triphenylamine, tetracyanoquinonedimethane, a transition metal oxide, and a transition metal chalcogenide compound;
the first electrode and the second electrode are independently selected from one of a metal oxide electrode, a doped metal oxide electrode, a composite electrode, a graphene electrode, a carbon nanotube electrode, a metal elemental electrode and an alloy electrode, wherein a material of the metal oxide electrode includes molybdenum oxide, a material of the doped metal oxide electrode includes one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide, the composite electrode includes one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnO, and ZnS/Al/ZnS, and a material of the metal elemental electrode includes one or more of Ag, Al, Cu, Mo, Au, Pt, Ca, Mg, and Ba; and
a material of the light-emitting layer includes an organic light-emitting material or a quantum dot light-emitting material; the organic light-emitting material includes one or more of 4,4′-bis(N-carbazole)-1,1′-biphenyl:tris[2-(p-tolyl)pyridine iridium(III), 4,4′,4″-tris(carbazol-9-yl)triphenylamine:tris[2-(p-tolyl)pyridinate iridium, diarylanthracene derivatives, stilbene aromatic derivatives, pyrene derivatives, fluorene derivatives, 1,4,7,10-tetratert-butylperylene, rubrene derivatives, thermally activated delayed fluorescent materials, exciplex luminescent materials, polyacetylene and its derivatives, polyp-phenylene and its derivatives, polythiophene and its derivatives, and polyfluorene and its derivatives; the quantum dot light-emitting material includes one or more of a single structure quantum dot and a core-shell structure quantum dot, wherein a material of the single structure quantum dot, a core material of the core-shell structure quantum dot, and a shell material of the core-shell structure quantum dot each include one or more of a Group II-VI compound, a Group IV-VI compound, a Group III-V compound, and a Group I-III-VI compound, the Group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe, the Group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe, and the Group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb, the Group I-III-VI compound is selected from one or more of CuInS₂, CuInSe₂, and AgInS₂.

In some embodiments, the first electrode has a thickness of 60 nm to 100 nm, the hole injection layer has a thickness of 10 nm to 50 nm, the hole transport layer has a thickness of 10 nm to 50 nm, the light-emitting layer has a thickness of 20 nm to 60 nm, the electron transport layer has a thickness of 40 nm to 120 nm, and the second electrode has a thickness of 60 nm to 100 nm.

### BRIEF DESCRIPTION OF DRAWINGS

In order to more clearly explain the technical solutions in the embodiments of the present disclosure, the accompanying drawings that need to be used in the description of the embodiments will be briefly described below.

FIG. 1 is a flowchart of a method of preparing a composite material according to an embodiment of the present disclosure.

FIG. 2 is a first schematic diagram of a light-emitting device according to an embodiment of the present disclosure.

FIG. 3 is a second schematic diagram of the light-emitting device according to an embodiment of the present disclosure.

### DETAILED DESCRIPTION

Technical solutions in embodiments of the present disclosure will be clearly and completely described below with reference to the figures in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, and the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural (multiple).

In the present disclosure, another layer is formed “on” a certain layer. The so-called term “upper” is a broad concept, which may mean that the other layer is formed adjacent to the certain layer, or may mean that another spacer structure layer exists between the other layer and the certain layer, for example, a second electrode is formed “on” a first carrier functional layer, and the so-called term “upper” may mean that the second electrode is formed adjacent to the first carrier functional layer, or may mean that another spacer structure layer exists between the second electrode and the first carrier functional layer, for example, a light-emitting layer.

Various embodiments of the present disclosure may be presented in a form of range. It should be understood that the description in the form of range is merely for convenience and brevity, and should not be construed as a hard limitation on the scope of the disclosure. Therefore, it should be considered that the recited range description has specifically disclosed all possible subranges, as well as a single numerical value within that range. For example, it should be considered that a description of a range from 1 to 6, more specifically, a range such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

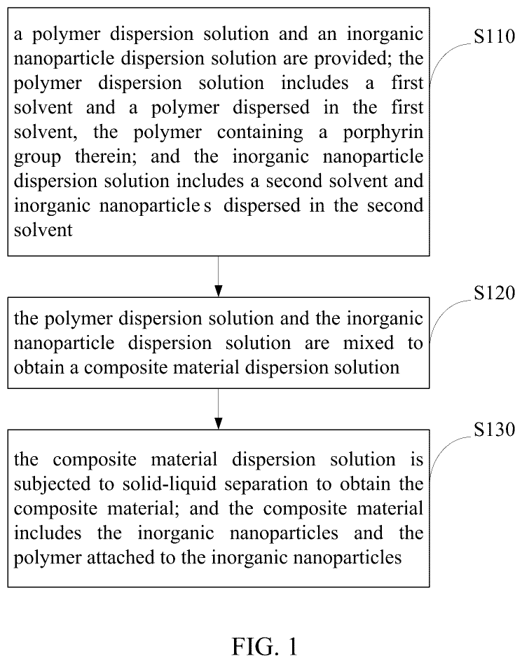

Referring to FIG. 1, embodiments of the present disclosure provide a composite material. The composite material includes inorganic nanoparticles and a polymer. The polymer is attached to the inorganic nanoparticles, and the polymer contains a porphyrin group.

The composite material provided by embodiments of the present disclosure includes the inorganic nanoparticle and the polymer attached to the inorganic nanoparticle. Since the polymer has the property of isolating water and oxygen, when the polymer is attached to the inorganic nanoparticle, the influence of external water and oxygen on the inorganic nanoparticle may be weakened or eliminated, so that the electrical properties of the inorganic nanoparticle remain stable. Since the porphyrin group in the polymer has conductive properties, the electron transport efficiency of the composite material may be improved.

In some embodiments, the polymer may coat a partial region or an entire region of the surface of the inorganic nanoparticle. The ratio between the partial region to the entire region may be in a range of from 0.1% to 99.9%, such as 0.1%, 0.5%, 1%, 5%, 10%, 20%, 30%, 40%, 50%, 60%, 70%, 80%, 90%, 99.9%, etc.

In some embodiments, the polymer is a porphyrin-based conjugated microporous polymer.

The porphyrin-based conjugated microporous polymer is a nitrogen-containing compound having a π-electron conjugated ring structure. The porphyrin-based conjugated microporous polymer is conducive to electron transport, so that it may improve the electron transport efficiency of the composite material. When an electron transport layer of a light-emitting device adopts the composite material, the electron transport efficiency of the electron transport layer may be improved, and the electrical performance of the light-emitting device may be improved.

In some embodiments, the porphyrin-based conjugated microporous polymer includes repeating units, each of the repeating units having a structure represented by formula (I):

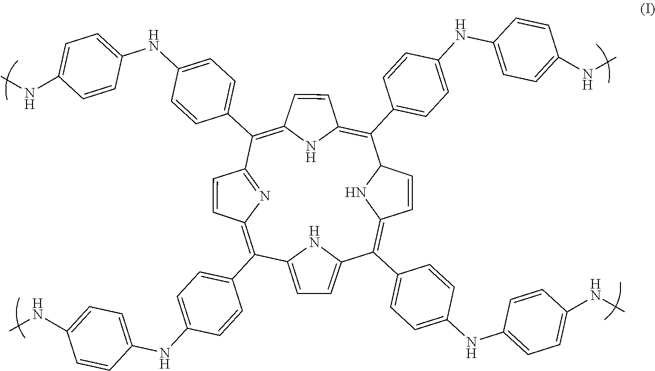

In the porphyrin-based conjugated microporous polymer, a number of the repeating units represented by the formula (I) is n, and n ranges from 2 to 10. For example, n may be 2, 3, 4, 5, 6, 7, 8, 9, or 10, etc.

In some embodiments, the method of preparing the porphyrin-based conjugated microporous polymer may include: mixing meso-tetra(p-bromophenyl)porphine, p-phenylenediamine, sodium tert-butoxide, 2-(dicyclohexylphosphino)-2,4,6-triisopropylbiphenyl, a catalyst and a third solvent at a normal temperature and a normal pressure, and reacting at a temperature of 100° C. to 120° C. (for example, 110° C.) for 40 hours to 56 hours to obtain the porphyrin-based conjugated microporous polymer.

A molar ratio of meso-tetra (p-bromophenyl) porphine, p-phenylenediamine, sodium tert-butoxide, 2-(dicyclohexylphosphino)-2,4,6-triisopropylbiphenyl and the catalyst is 1:(2-5):(4-6):(0.1-0.14):(0.06-0.1). In some embodiments, the catalyst may be a palladium metal catalyst, such as bis(dibenzylideneacetone) palladium or the like. In some embodiments, the third solvent may include one or more of xylene, ethylbenzene, xylene, m-diethylbenzene, and p-diethylbenzene.

In some embodiments, the polymer includes a plurality of micropores. The pore size of a micropore ranges from 0.01 nm to 2 nm (e.g., 0.01 nm, 0.03 nm, 0.05 nm, 0.08 nm, 0.1 nm, 0.3 nm, 0.5 nm, 0.8 nm, 1 nm, 1.3 nm, 1.5 nm, 1.8 nm, 2 nm, etc.), and a total volume of the plurality of micropores accounts for 15% to 40% (e.g., 15%, 20%, 25%, 30%, 35%, 40%, etc.) of a volume of the polymer. It should be noted that when the porosity of the polymer (a volume ratio of the total volume of multiple micropores in the polymer) is higher, the electrical conductivity of the polymer is higher, which helps to improve the electron transport efficiency of the composite material. When the composite material is used as an electron transport layer material of the light-emitting device, the electron transport efficiency of the electron transport layer may be improved, thereby improving the electrical properties of the light-emitting device.

In some embodiments, the inorganic nanoparticle is an electron transport material. The electron transport material includes one or more of a metal oxide, a doped metal oxide, a Group II-VI semiconductor material, a Group III-V semiconductor material and a Group I-III-VI semiconductor material. The metal oxide is selected from one or more of ZnO, BaO, TiO₂, and SnO₂. A metal oxide of the doped metal oxide is selected from one or more of ZnO, TiO₂, and SnO₂, and a doping element of the doped metal oxide is selected from one or more of Al, Mg, Li, In, and Ga. The Group II-VI semiconductor material is selected from one or more of ZnS, ZnSe, and CdS. The Group III-V semiconductor material is selected from one or more of InP and GaP. The Group I-III-VI semiconductor material is selected from one or more of CuInS and CuGaS.

In some embodiments, the inorganic nanoparticle is a zinc oxide nanoparticle.

In some embodiments, a particle size D50 of the zinc oxide nanoparticle may range from 0.1 nm to 6 nm, such as 0.1 nm, 0.5 nm, 1 nm, 1.5 nm, 2 nm, 2.5 nm, 3 nm, 3.5 nm, 4 nm, 4.5 nm, 5 nm, 5.5 nm, 6 nm, etc.

In some embodiments, a mass ratio of the polymer to the inorganic nanoparticles in the composite material is (1-5):20, for example, 1:20, 2:20, 3:20, 4:20, 5:20, etc.

In some embodiments, the composite material further includes a surfactant. The surfactant is distributed at least on the outer surface of the inorganic nanoparticles. A molar ratio of the surfactant to the inorganic nanoparticles is 1:(2-8), for example, 1:2, 1:3, 1:4, 1:5, 1:6, 1:7, 1:8, etc.

It should be noted that the surfactant distributed on the outer surface of the inorganic nanoparticle may change the surface properties of the inorganic nanoparticle, so that the inorganic nanoparticle is more easily attached to the polymer, that is, the binding force between the polymer and the inorganic nanoparticle is stronger, and thus the structural stability of the composite material may be improved.

In some embodiments, a portion of the surfactant is distributed on the outer surface of the inorganic nanoparticle. The other part of the surfactant may be distributed on an inner surface of the polymer, or may be distributed on the outer surface of the polymer, or may be distributed on both the inner surface of the polymer and the outer surface of the polymer.

The composite material provided by embodiments of the present disclosure includes the inorganic nanoparticle and the polymer attached to the inorganic nanoparticle. Since the polymer has the property of isolating water and oxygen, when the polymer is attached to the inorganic nanoparticle, the influence of external water and oxygen on the inorganic nanoparticle may be weakened or eliminated, so that the electrical properties of the inorganic nanoparticle remain stable. Since the porphyrin group in the polymer has conductive properties, the electron transport efficiency of the composite material may be improved. When the electron transport layer of the light-emitting device adopts the composite material, the electron transport efficiency of the electron transport layer may be improved, and the electron injection barrier between the electron transport layer and the light-emitting layer may be reduced, thereby facilitating the realization of carrier balance in the light-emitting layer, thereby improving the electrical performance of the light-emitting device.

Since the polymer itself has a dielectric effect, the electron injection efficiency of the inorganic nanoparticle may be flexibly adjusted by adjusting a ratio of the polymer and the inorganic nanoparticle. Since the polymer has a limiting effect, the inorganic nanoparticle may be uniformly dispersed in the polymer and the position of the inorganic nanoparticle may be kept relatively fixed, so that the problem of uneven film thickness after deposition due to agglomeration of the inorganic nanoparticle may be avoided.

Referring to FIG. 1, embodiments of the present disclosure further provide a method of preparing a composite material, which can be used for preparing the composite material in any of the above embodiments. The method of preparing the composite material includes step S110, step S120, and step S130.

In step S 110, a polymer dispersion solution and an inorganic nanoparticle dispersion solution are provided; the polymer dispersion solution includes a first solvent and a polymer dispersed in the first solvent, the polymer containing a porphyrin group therein; and the inorganic nanoparticle dispersion solution includes a second solvent and inorganic nanoparticles dispersed in the second solvent.

In some embodiments, the step of providing the polymer dispersion solution includes: providing the polymer, and dissolving the polymer in the first solvent to obtain the polymer dispersion solution.

In some embodiments, the polymer is a porphyrin-based conjugated microporous polymer. The step of providing the polymer includes the following step. In the step, meso-tetra (p-bromophenyl) porphine, p-phenylenediamine, sodium tert-butoxide, 2-(dicyclohexylphosphino)-2,4,6-triisopropylbiphenyl, a catalyst and a third solvent are mixed and reacted at a temperature of 100° C. to 120° C. (e.g., 110° C.) for 40 hours to 56 hours to obtain the porphyrin-based conjugated microporous polymer. A molar ratio of meso-tetra(p-bromophenyl)porphine, p-phenylenediamine, sodium tert-butoxide, 2-(dicyclohexylphosphino)-2,4,6-triisopropylbiphenyl and the catalyst is 1:(2-5):(4-6):(0.1-0.14):(0.06-0.1). In some embodiments, the molar ratio of meso-tetra(p-bromophenyl)porphine, p-phenylenediamine, sodium tert-butoxide, 2-(dicyclohexylphosphino)-2,4,6-triisopropylbiphenyl and the catalyst is 1:3:5:0.12:0.08. In some embodiments, the catalyst may be a palladium metal catalyst, such as bis (dibenzylideneacetone) palladium or the like. In some embodiments, the third solvent may include one or more of xylene, ethylbenzene, xylene, m-diethylbenzene, and p-diethylbenzene.

In some embodiments, the step of providing the inorganic nanoparticle dispersion solution includes the following step. In the step, the inorganic nanoparticles are provided, and the inorganic nanoparticles are dissolved in the second solvent to obtain the inorganic nanoparticle dispersion solution.

In some embodiments, the inorganic nanoparticles are zinc oxide nanoparticles. The step of providing the inorganic nanoparticles includes the following step. In the step, a precipitant solution and a zinc salt solution are mixed and reacted at a temperature condition of 50° C. to 70° C. for 2 hours to 3 hours to obtain the zinc oxide nanoparticles. A molar ratio of a precipitant to a zinc salt is (1-2):6, for example, 1:6, 1.5:6, 2:6, etc. In some embodiments, the precipitant includes one or more of hexamethylenetetramine, sodium hydroxide (NaOH), lithium hydroxide (LiOH), potassium hydroxide (KOH), tetramethylammonium hydroxide.

In some embodiments, the inorganic nanoparticle dispersion solution further includes a surfactant, and a molar ratio of the surfactant to the inorganic nanoparticles is 1:(2-8), such as 1:2, 1:3, 1:4, 1:5, 1:6, 1:7, 1:8, etc.

In some embodiments, the first solvent may include one or more of ethanol, toluene, chlorobenzene, methanol, butanol, anisole.

In some embodiments, the second solvent may include one or more of ethanol, methanol, butanol, isopropanol, acetonitrile, ethylene glycol methyl ether.

In some embodiments, the step of providing the polymer dispersion solution includes dissolving the polymer in the first solvent and ultrasonically dispersing for 10 minutes to 30 minutes (e.g., 20 minutes) to obtain the polymer dispersion solution.

In some embodiments, the step of providing the inorganic nanoparticle dispersion solution includes dissolving the inorganic nanoparticles in the second solvent and ultrasonically dispersing the inorganic nanoparticles for 5 minutes to 30 minutes (e.g., 20 minutes) to obtain the inorganic nanoparticle dispersion solution.

In step S120, the polymer dispersion solution and the inorganic nanoparticle dispersion solution are mixed to obtain a composite material dispersion solution.

In some embodiments, the step of mixing the polymer dispersion solution and the inorganic nanoparticle dispersion solution includes mixing the polymer dispersion solution and the inorganic nanoparticle dispersion solution at a temperature of 3° C. to 10° C., and stirring for 5 hours to 10 hours after mixing. Among them, the temperature condition of 3° C. to 10° C. may be, for example, 3° C., 4° C., 5° C., 6° C., 7° C., 8° C., 9° C., 10° C., or the like. The stirring for 5 hours to 10 hours may be, for example, 5 hours, 6 hours, 7 hours, 8 hours, 9 hours, 10 hours, or the like. It is understood that by stirring, not only the polymer and the inorganic nanoparticles may be uniformly mixed, but also the polymer and the inorganic nanoparticles may be tightly joined to form a structurally stable composite material.

In some embodiments, a mass ratio of the polymer to the inorganic nanoparticles in the composite dispersion solution is (1-5): 20. For example, the mass ratio may be 1:20, 2:20, 3:20, 4:20, 5:20, or the like.

In some embodiments, a concentration of the composite material in the composite material dispersion solution ranges from 15 mg/mL to 30 mg/mL. For example, the concentration may be 15 mg/mL, 20 mg/mL, 25 mg/mL, 30 mg/mL, and the like.

In step S130, the composite material dispersion solution is subjected to solid-liquid separation to obtain the composite material; and the composite material includes the inorganic nanoparticles and the polymer attached to the inorganic nanoparticles.

In some embodiments, the solid-liquid separation of the composite material dispersion solution may be performed by filtration, suction filtration, and the like.

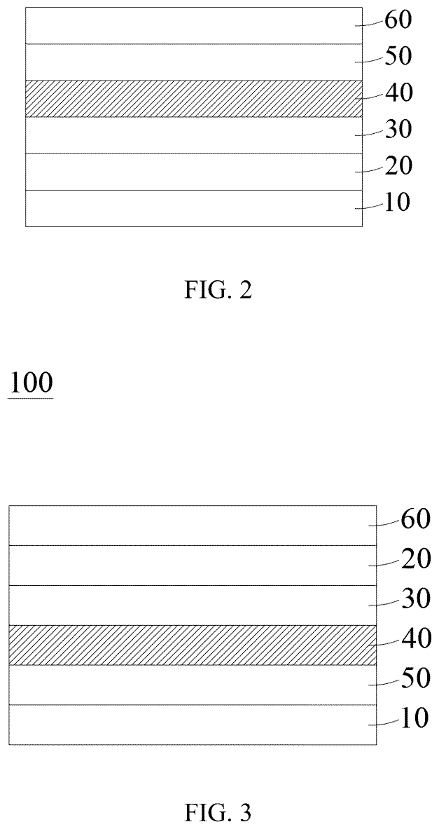

Referring to FIGS. 2 and 3, embodiments of the present disclosure further provide a light-emitting device 100. The light-emitting device 100 includes a first electrode 10, a second electrode 60, an electron transport layer 50 and a light-emitting layer 40. The first electrode 10 and the second electrode 60 are disposed opposite each other, and the electron transport layer 50 and the light-emitting layer 40 are disposed between the first electrode 10 and the second electrode 60. A material of the electron transport layer 50 is the composite material in any of the above embodiments or the composite material prepared by the method for preparing the composite material in any of the above embodiments.

Referring to FIGS. 2 and 3, the light-emitting device 100 further includes a hole transport layer 30 and a hole injection layer 20.

Referring to FIG. 2, when the first electrode 10 is an anode and the second electrode 60 is a cathode, the light-emitting layer 40, the hole transport layer 30, and the hole injection layer 20 are disposed between the electron transport layer 50 and the first electrode 10, and the light-emitting layer 40, the hole transport layer 30, and the hole injection layer 20 are stacked in this order in the direction from the electron transport layer 50 to the first electrode 10.

Referring to FIG. 3, when the first electrode 10 is the cathode and the second electrode 60 is the anode, the light-emitting layer 40, the hole transport layer 30, and the hole injection layer 20 are disposed between the electron transport layer 50 and the second electrode 60, and the light-emitting layer 40, the hole transport layer 30, and the hole injection layer 20 are stacked in this order in the direction from the electron transport layer 50 to the second electrode 60.

In some embodiments, a material of the hole transport layer 30 includes one or more of 4,4′-N,N′-dicarbazolyl-biphenyl (CBP), poly[bis(4-phenyl)(2,4,6-trimethylphenyl)amine](PTAA), N,N′-diphenyl-N,N′-bis(1-naphthyl)-1,1′-biphenyl-4,4″-diamine (a-NPD), N,N′-diphenyl-N,N′-bis(3-methylphenyl)-(1,1′-biphenyl)-4,4′-diamine (TPD), poly(N,N′-bis(4-butylphenyl)-N,N′-bis(phenyl)benzidine) (Poly-TPD), N,N′-bis(4-(N,N′-diphenyl-amino)phenyl)-N,N′-diphenylbenzidine (DNTPD), 4,4′,4′-tris(N-carbazolyl)-triphenylamine (TCTA), 4,4′,4′-tris(N-3-methylphenyl-N-phenylamino)triphenylamine (m-MTDATA), poly[(9,9′-dioctylfluorene-2,7-diyl)-co-(4,4′-(N-(4-sec-butylphenyl)diphenylamine))](TFB), poly(N-vinylcarbazole) (PVK) and its derivatives, N,N′-bis(1-naphthyl)-N,N′-diphenyl-1,1′-biphenyl-4-4′-diamine (NPB), poly(phenylenevinylene) (PPV), poly[2-methoxy-5-(2-ethylhexyloxy)-1,4-phenylenevinylene](MEH-PPV), poly[2-methoxy-5-(3′,7′-dimethyloctyloxy)-1,4-phenylenevinylene](MOMO-PPV), 2,2′,7,7′-tetrakis[N,N-bis(4-methoxyphenyl)amino]-9,9′-spirobifluorene (spiro-omeTAD), 4,4′-cyclohexylbis[N,N-bis(4-methylphenyl)aniline](TAPC), 1,3-bis(carbazol-9-yl)benzene (MCP), polyaniline, polypyrrole, poly(p-phenylenevinylene), aromatic tertiary amines, polynuclear aromatic tertiary amines, 4,4′-bis(p-carbazol-9-yl)-1,1′-biphenyl compounds, N,N,N′,N′-tetraarylbenzidine, poly(3,4-ethylenedioxythiophene)-polystyrene sulfonic acid (PEDOT:PSS) and its derivatives, polymethacrylate and its derivatives, Poly(9,9-octylfluorene) and its derivatives, polyspirofluorene and its derivatives, polythiophene (TPH) and its derivatives.

In some embodiments, a material of the hole injection layer 20 includes one or more of poly(3,4-ethylenedioxythiophene)-polystyrenesulfonic acid (PEDOT:PSS), copper phthalocyanine (CuPc), dipyrazino[2,3-f:2′,3′-h]quinoxaline-2,3,6,7,10,11-hexacarbonitrile (HAT-CN), polydioxyethyl thiophene (PEDOT), PEDOT:PSS derivatives doped with MoO₃ (PEDOT:PSS-MoO₃), 4,4′,4″-tris(N-3-methylphenyl-N-phenylamino)triphenylamine (m-MTDATA). tetracyanoquinodimethane (F4-TCNQ), a transition metal oxide and a transition metal chalcogenide compound. In some embodiments, the transition metal oxide may include one or more of MoOₓ, VOₓ, WOₓ, CrOₓ, and CuO. In some embodiments, the transition metal chalcogenide compound may include one or more of MoS₂, MoSe₂, WS₂, WSe₂, and CuS.

In some embodiments, the first electrode 10 and the second electrode 60 may each independently be selected from one of a metal oxide electrode, a doped metal oxide electrode, a composite electrode, a graphene electrode, a carbon nanotube electrode, a metal elemental electrode and an alloy electrode. A material of the metal oxide electrode may be molybdenum oxide (MoO₃). A material of the doped metal oxide electrode may include, but is not limited to, one or more of indium-doped tin oxide (ITO), fluorine-doped tin oxide (FTO), antimony-doped tin oxide (ATO), aluminum-doped zinc oxide (AZO), gallium-doped zinc oxide (GZO), indium-doped zinc oxide (IZO), magnesium-doped zinc oxide (MZO), aluminum-doped magnesium oxide (AMO), and cadmium-doped zinc oxide. The composite electrode may be an electrode formed by laminating two or more conductive materials, and may be, for example, AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, Ca/Al, LiF/Ca, LiF/Al, BaF₂/Al, CsF/Al, CaCO₃/Al, BaF₂/Ca/Al, or the like. Here, “/” represents a laminated structure, and for example, AZO/Ag/AZO represents a composite electrode including an AZO layer, an Ag layer, and an AZO layer stacked in this order. A material of the metal elemental electrode may include, but is not limited to, silver (Ag), magnesium (Mg), aluminum (Al), gold (Au), gallium (Ga), nickel (Ni), platinum (Pt), iridium (Ir), copper (Cu), molybdenum (Mo), One or more of calcium (Ca) and barium (Ba). The alloy electrode includes, but is not limited to, an Au:Mg alloy electrode or an Ag:Mg alloy electrode.

In some embodiments, one of the first electrode 10 and the second electrode 60 as an anode may be an electrode having a relatively high work function, for example, may include, but is not limited to, one or more of a doped metal oxide electrode having a relatively high work function, a metal elemental electrode having a relatively high work function, and a carbon nanotube electrode; The material of the metal elemental electrode having a relatively high function may be Ni, Pt, Au, Ag, Ir, or the like.

In some embodiments, one of the first electrode 10 and the second electrode 60 as a cathode may be an electrode having a relatively low work function, for example, may include, but are not limited to, a metal elemental electrode having a relatively low work function, a composite electrode having a relatively low work function, and a alloy electrode having a relatively low work function. A material of the metal elemental electrode having a relatively low work function may be Ca, Ba, Al, Mg, or the like. A structure of the composite electrode having a relatively low work function may be Ca/Al, LiF/Ca, LiF/Al, BaF₂/Al, CsF/Al, CaCO₃/Al, BaF₂/Ca/Al, or the like. The alloy electrode having a relatively low work function may be Au:Mg, Ag:Mg, or the like.

In some embodiments, a material of the light-emitting layer 40 may include an organic light-emitting material or a quantum dot light-emitting material.

In some embodiments, the organic light-emitting material may include, but is not limited to, one or more of 4,4′-bis(N-carbazole)-1,1′-biphenyl:tris[2-(p-tolyl)pyridine iridium(III) (CBP:Ir(mppy)₃), 4,4′,4″-tris(carbazol-9-yl)triphenylamine:tris[2-(p-tolyl)pyridinate iridium (TCTX:Ir(mmpy)), diarylanthracene derivatives, stilbene aromatic derivatives, pyrene derivatives, fluorene derivatives, 1,4,7,10-tetratert-butylperylene (TBPe), rubrene derivatives (TBRb), thermally activated delayed fluorescent (TADF) materials, luminescent materials having hybrid local-charge transfer (HLCT) excited state characteristics, exciplex luminescent materials, polyacetylene and its derivatives, polyp-phenylene and its derivatives, polythiophene and its derivatives, polyfluorene and its derivatives.

In some embodiments, the quantum dot light-emitting material includes one or more of a single structure quantum dot and a core-shell structure quantum dot, specifically, a material of the single structure quantum dot, a core material of the core-shell structure quantum dot, and a shell material of the core-shell structure quantum dot may each include one or more of a Group II-VI compound, a Group IV-VI compound, a Group III-V compound, and a Group I-III-VI compound. The Group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe. The Group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe, and the Group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb, the Group I-III-VI compound is selected from one or more of CuInS₂, CuInSe₂, and AgInS₂.

In some embodiments, a thickness of the first electrode 10 is 60 nm-100 nm, such as 60 nm, 70 nm, 80 nm, 90 nm, 100 nm, etc.

In some embodiments, a thickness of the hole injection layer 20 is 10 nm-50 nm, such as 10 nm, 20 nm, 30 nm, 40 nm, 50 nm, etc.

In some embodiments, a thickness of the hole transport layer 30 is 10 nm-50 nm, such as 10 nm, 20 nm, 30 nm, 40 nm, 50 nm, etc.

In some embodiments, a thickness of the light-emitting layer 40 is 20 nm-60 nm, for example, 20 nm, 30 nm, 40 nm, 50 nm, 60 nm, etc.

In some embodiments, a electron transport layer 50 has a thickness of 40 nm-120 nm, such as 40 nm, 60 nm, 80 nm, 100 nm, 120 nm, etc.

In some embodiments, a thickness of the second electrode 60 is 60 nm-100 nm, such as 60 nm, 70 nm, 80 nm, 90 nm, 100 nm, etc.

Referring to FIGS. 2 and 3, embodiments of the present disclosure also provide a method of preparing a light-emitting device, which can be used for preparing the light-emitting device 100 in any of the above embodiments, and the method of preparing the light-emitting device 100 includes steps S210, S220, and S230.

In step S210, a light-emitting device preform including a first electrode 10 is provided.

In step S220, an electron transport layer 50 is formed on the light-emitting device preform, and a material of the electron transport layer 50 includes the above-described composite material.

In some embodiments, the step of forming the electron transport layer 50 on the light-emitting device preform includes the following steps.

A polymer dispersion solution and an inorganic nanoparticle dispersion solution are provided. The polymer dispersion solution includes a first solvent and a polymer dispersed in the first solvent, and the polymer contains a porphyrin group. The inorganic nanoparticle dispersion solution includes a second solvent and inorganic nanoparticles dispersed in the second solvent.

The polymer dispersion solution and the inorganic nanoparticle dispersion solution are mixed to obtain a composite material dispersion solution.

The composite material dispersion solution is applied to the light-emitting device preform to obtain a wet film layer, and the wet film layer is annealed to obtain the electron transport layer 50.

In some embodiments, the step of annealing the wet film layer includes heat treating the wet film layer at a temperature of 60° C. to 100° C. (e.g., 80° C.) for a treatment time of 20 minutes to 40 minutes (e.g., 20 minutes).

In step S230, a second electrode 60 is formed on the electron transport layer 50 to obtain the light-emitting device 100.

Referring to FIG. 2, when the first electrode 10 is an anode and the second electrode 60 is a cathode, the light-emitting device preform further includes a hole injection layer 20, a hole transport layer 30, and a light-emitting layer 40 disposed between the first electrode 10 and the electron transport layer 50, and the hole injection layer 20, the hole transport layer 30, and the light-emitting layer 40 are stacked in this order in a direction from the first electrode 10 to the electron transport layer 50.

Referring to FIG. 3, when the first electrode 10 is the cathode and the second electrode 60 is the anode, the step of forming the second electrode 60 on the electron transport layer 50 includes forming the light-emitting layer 40 on the electron transport layer 50, forming the hole transport layer 30 on the light-emitting layer 40, forming the hole injection layer 20 on the hole transport layer 30, and forming the second electrode 60 on the hole injection layer 20.

Referring to FIGS. 2 and 3, embodiments of the present disclosure further provide a display device including the light-emitting device in any one of the above embodiments or a light-emitting device prepared by the method in any one of the above embodiments.

Hereinafter, a composite material and a preparation method thereof, a light-emitting device and a preparation method thereof of the present disclosure will be described in detail in the form of specific embodiments.

### Composite Material Example 1

A composite material whose preparation method includes the following steps.

In Step 11, two monomers of meso-tetra(p-bromophenyl) porphine (186 mg, 0.2 mmol) and p-phenylenediamine (64.8 mg, 0.6 mmol) were added to a 50 mL reaction tube at normal temperature and pressure, sodium tert-butoxide (100 mg, 1.04 mmol), 2-(dicyclohexylphosphino)-2,4,6-triisopropylbiphenyl (11.44 mg, 0.024 mmol), and bis(dibenzylideneacetone) palladium (9.2 mg, 0.016 mmol) were added, and then 20 mL of anhydrous toluene was added under a nitrogen atmosphere, and reacted at 110° C. for 48 hours to obtain a polymer. First, the polymer was washed with chloroform, methanol and water, and then dried in a vacuum oven at 100° C. for 48 hours to obtain a porphyrin-based conjugated microporous polymer. The porphyrin-based conjugated microporous polymer includes repeating units, and each of the repeating units has a structure represented by formula (I).

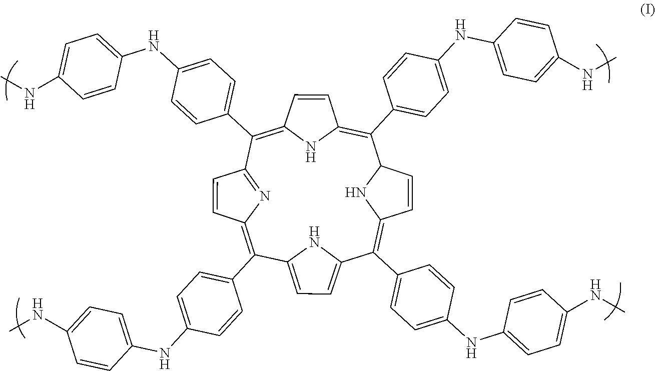

In the porphyrin-based conjugated microporous polymer, a number n of the repeating unit represented by the formula (I) is 5 to 6.

In step 12, 200 mg of zinc acetate was dissolved in 50 mL of ethanol to obtain a first solution. In addition, 70 mg of hexamethylenetetramine was dissolved in 50 mL of DMSO to obtain a second solution. The first solution and the second solution were mixed, and stirred for 5 minutes, then transferred to a 200 mL flask, a reaction temperature was maintained at 60° C., and a hydrothermal reaction was carried out for 2 hours, and then naturally cooled to obtain a reaction product. The reaction product is suction filtered, washed with ethanol and n-octane for three times, and finally dried to obtain nano spherical zinc oxide particles.

In step 13, 37 mg of sodium dodecyl sulfonate was dissolved in 50 ml of ethanol to obtain a mixed solution. 100 mg of nano-zinc oxide was added into the mixed solution, and ultrasonically stirred for 10 minutes to make the zinc oxide form stably dispersed nanosol. The nanosol was placed in an incubator at 5° C., continuously stirred, 10 mg of the porphyrin-based conjugated microporous polymer was added to the nanosol, stirred for 30 minutes to fully dissolve the nanosol, and the reaction was continued to stir for 8 hours after the addition was completed to obtain a reaction mixture. After the reaction, the reaction mixture was repeatedly filtered and washed with deionized water and methanol to obtain a composite material. The composite material was zinc oxide modified by the porphyrin-based conjugated microporous polymer.

### Composite Material Example 2

This embodiment provides a composite material. Compared with Composite Material Example 1, the preparation method of the composite material is different in that step 13 is changed to the following content.

In step 13, 5 mg of the porphyrin-based conjugated microporous polymer was added to the nanosol, mixing it with 100 mg of nano-zinc oxide.

### Composite Material Example 3

This embodiment provides a composite material. Compared with Composite Material Example 1, the preparation method of the composite material is different in that step 13 is changed to the following content.

In step 13, 20 mg of the porphyrin-based conjugated microporous polymer was added to the nanosol, mixing it with 100 mg of nano-zinc oxide.

### Device Example 1

A method of preparing a QLED includes steps 21 to 27.

In step 21, a patterned ITO substrate was sequentially placed in acetone, a cleaning solution, deionized water, and isopropyl alcohol, and ultrasonically cleaned. Each ultrasonic cleaning step lasted for 15 minutes. After ultrasonication, the ITO substrate was placed in a clean oven to dry for later use.

In step 22, after the ITO substrate was dried, the surface of the ITO substrate was treated with ultraviolet-ozone treatment for 5 minutes to further remove organic matter attached to the surface of the ITO substrate and improve the work function of the ITO.

In step 23, a hole injection layer (PEDOT:PSS) was deposited on the surface of the ITO substrate, with a thickness of 30 nm. The ITO substrate was heated on a heating table at 150° C. for 30 minutes to remove moisture. This step was done in air.

In step 24, the dried ITO substrate with the hole injection layer was placed in a nitrogen atmosphere. A hole transport layer (TFB) was deposited to obtain a substrate on which the hole transport layer was deposited. A thickness of the hole transport layer was 30 nm. The substrate on which the hole transport layer was deposited was placed on a heating table at 150° C. and heated for 30 minutes to remove the solvent to obtain a device having the hole transport layer.

In step 25, the device having the hole transport layer produced in the previous step was cooled. Then, a quantum dot light-emitting layer was deposited on the surface of the hole transport layer to obtain a device having a light-emitting layer. A thickness of the quantum dot light-emitting layer was 40 nm. After the deposition step of this step was completed, the device having the light-emitting layer was placed on a heating table at 80° C. and heated for 10 minutes to remove the residual solvent.

In Step 26, the composite material from Composite Material Example 1 was dispersed in ethanol to obtain a composite material solution having a concentration of 25 mg/mL. The composite material solution was spin-coated on the quantum dot light-emitting layer at a spin-coating speed of 3000 rpm to obtain a thin film. The thin film was heat treated at 80° C. for 30 minutes to obtain an electron transport layer, with a thickness of 80 nm, resulting in a device with multiple functional layers.

In step 27, the device with multiple functional layers was placed in a vapor deposition chamber. A layer of Ag, serving as the cathode, was thermally evaporated through a mask, with a thickness of 80 nm. The QLED was thus prepared.

### Device Example 2

This embodiment provides a QLED. Compared with Device Example 1, the method of preparing the QLED is different in that step 26 is changed to the following content.

In Step 26, the composite material from Composite Material Example 2 was dispersed in ethanol to obtain a composite material solution having a concentration of 25 mg/mL.

### Device Example 3

This embodiment provides a QLED. Compared with Device Example 1, the method of preparing the QLED is different in that step 26 is changed to the following content.

In Step 26, the composite material from Composite Material Example 3 was dispersed in ethanol to obtain a composite material solution having a concentration of 25 mg/mL.

### Device Example 4

This embodiment provides a QLED. Compared with Device Example 1, the method of preparing the QLED is different in that step 26 is changed to the following content.

In step 26, the electron transport layer prepared had a thickness of 40 nm.

### Device Example 5

This embodiment provides a QLED. Compared with Device Example 1, the method of preparing the QLED is different in that step 26 is changed to the following content.

In step 26, the electron transport layer prepared had a thickness of 120 nm.

### Device Comparative Example 1

A QLED whose preparation method differs from Device Example 1 only in that step 26 is different. In Step 26 of Device Comparative Example 1 of the device, a zinc oxide nanoparticle solution was spin-coated on the quantum dot light-emitting layer at a spin-coating speed of 3000 rpm, and the spin-coated film was heat-treated at 80° C. for 30 minutes to obtain an electron transport layer, and a thickness of the electron transport layer is 80 nm.

As can be seen, the difference between the QLED of Device Comparative Example 1 and the QLED of Device Example 1 was only that the material of the electron transport layer is different. The material of the electron transport layer in Device Comparative Example 1 was unmodified zinc oxide nanoparticles, whereas the material of the electron transport layer in Device Example 1 was the composite material (that is zinc oxide modified by the porphyrin-based conjugated microporous polymer).

The performance tests were carried out on QLEDs prepared in Device Examples 1-5 and QLEDs prepared in Device Comparative Example 1. Among them, The T95@1000 nit/(h) was mainly tested by a life test system consisting of Keithley 2400 digital source meter, CS-160 luminance meter and photodiode detector, and the external quantum efficiency (EQE) was measured by EQE optical test instrument. The test results are shown in Table 1.

TABLE 1

Items

| Group | T95@1000 nit/(h) | EQE/(%) |
|---|---|---|
| Device Example 1 | 70 | 18.8 |
| Device Example 2 | 75 | 19.1 |
| Device Example 3 | 65 | 17.5 |
| Device Example 4 | 54 | 15.5 |
| Device Example 5 | 62 | 16.1 |
| Device Comparative Example 1 | 20 | 8.2 |

The following can be seen from Table 1. The service life (T95 @1000 nit) of the QLEDs in Device Examples 1-5 is greater than that of the QLED in Device Comparative Example 1, indicating that the QLEDs in Device Examples 1-5 have a longer service life. The external quantum efficiency (EQE) of the QLEDs in Device Examples 1-5 is also greater than that of the QLED in Device Comparative Example 1, indicating higher luminous efficiency. Thus, the QLEDs in Device Examples 1-5 exhibit better electrical properties and stability compared to the QLED in Device Comparative Example 1. This improvement is attributed to the material used for the electron transport layer in Device Examples 1-5, which is a composite material (zinc oxide modified by a porphyrin-based conjugated microporous polymer). Compared to unmodified nano-zinc oxide, the zinc oxide modified by the porphyrin-based conjugated microporous polymer has higher electron transport efficiency. This enhancement improves the electron transport efficiency of the electron transport layer and reduces the electron injection barrier between the electron transport layer and the light-emitting layer, thus helping to achieve carrier balance and improve the electrical properties of the light-emitting device. Additionally, the porphyrin-based conjugated microporous polymer has properties that isolate water and oxygen. When connected to the inorganic nanoparticle, it may weaken or eliminate the influence of external water and oxygen, thereby maintaining the stability of the inorganic nanoparticle's performance.

By comparing Device Example 1, Device Example 2 and Device Example 3, it may be seen that the QLED in Device Example 2 has the longest service life (T95 @1000 nit) and the largest external quantum efficiency (EQE), which shows that when the mass ratio of the porphyrin-based conjugated microporous polymer to nano-zinc oxide is 1:20, the QLED has better electrical properties.

By comparing Device Example 1, Device Example 4 and Device Example 5, it may be seen that the QLED in Device Example 1 has the longest service life (T95 @1000 nit) and the largest external quantum efficiency (EQE), indicating that when the thickness of the electron transport layer is 80 nm, the QLED has better electrical properties.

The technical solutions provided by embodiments of the present disclosure have been described in detail above. Herein, the principles and embodiments of the present disclosure are described with specific examples, and the above description of the embodiments is merely for helping to understand the present disclosure. Meanwhile, those skilled in the art may change the specific embodiments and the scope of application according to the ideas of the present disclosure, and in summary, the contents of the present specification should not be construed as limiting the present disclosure.

What is claimed is:

1. A composite material comprising inorganic nanoparticles and a polymer, wherein the polymer is attached to the inorganic nanoparticles, and the polymer contains a porphyrin group.

2. The composite material according to claim 1, wherein the polymer is a porphyrin-based conjugated microporous polymer.

3. The composite material according to claim 2, wherein the porphyrin-based conjugated microporous polymer comprises repeating units, each of the repeating units having a structure represented by formula (I): 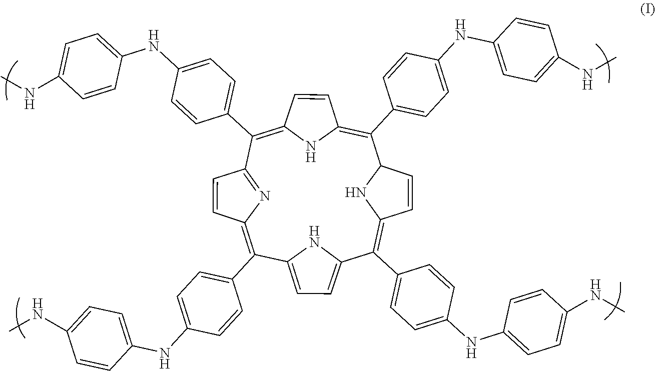
in the porphyrin-based conjugated microporous polymer, a number of the repeating units is n, and n ranges from 2 to 10.

4. The composite material according to claim 1, wherein the polymer comprises multiple micropores, each with a pore size ranging from 0.01 nm to 2 nm, and a total volume of the micropores accounts for 15% to 40% of a volume of the polymer.

5. The composite material according to claim 1, wherein the inorganic nanoparticles are selected from one or more of a metal oxide, a doped metal oxide, a Group II-VI semiconductor material, a Group III-V semiconductor material and a Group I-III-VI semiconductor material;
the metal oxide is selected from one or more of ZnO, BaO, TiO₂, and SnO₂;
a metal oxide of the doped metal oxide is selected from one or more of ZnO, TiO₂, and SnO₂, and a doping element of the doped metal oxide is selected from one or more of Al, Mg, Li, In, and Ga;
the Group II-VI semiconductor material is selected from one or more of ZnS, ZnSe, and CdS;
the Group III-V semiconductor material is selected from one or more of InP and GaP; and
the Group I-III-VI semiconductor material is selected from one or more of CuInS and CuGaS.

6. The composite material according to claim 1, wherein a mass ratio of the polymer to the inorganic nanoparticles is (1-5):20.

7. The composite material according to claim 1, wherein the composite material further comprises a surfactant, the surfactant being distributed at least on the outer surface of the inorganic nanoparticles, and a molar ratio of the surfactant to the inorganic nanoparticles is 1:(2-8).

8. A method of preparing a composite material, comprising:
providing a polymer dispersion solution and an inorganic nanoparticle dispersion solution; wherein the polymer dispersion solution comprises a first solvent and a polymer dispersed in the first solvent, the polymer containing a porphyrin group therein; and the inorganic nanoparticle dispersion solution comprises a second solvent and inorganic nanoparticles dispersed in the second solvent;
mixing the polymer dispersion solution and the inorganic nanoparticle dispersion solution to obtain a composite material dispersion solution; and
performing solid-liquid separation on the composite material dispersion solution to obtain a composite material, wherein the composite material comprises a polymer and a plurality of inorganic nanoparticles uniformly dispersed inside the polymer.

9. The method according to claim 8, wherein a mass ratio of the polymer to the inorganic nanoparticles in the composite material dispersion solution is (1-5):20;
the step of mixing the polymer dispersion solution and the inorganic nanoparticle dispersion solution comprises: mixing the polymer dispersion solution and the inorganic nanoparticle dispersion solution at a temperature of 3° C. to 10° C., and stirring for 5 hours to 10 hours after mixing.

10. The method according to claim 8, wherein the inorganic nanoparticle dispersion solution further comprises a surfactant, and a molar ratio of the surfactant to the inorganic nanoparticles is 1:(2-8).

11. The method according to claim 8, wherein the step of providing the polymer dispersion solution comprises: providing the polymer and dissolving the polymer in the first solvent to obtain the polymer dispersion solution.

12. The method according to claim 11, wherein the polymer is a porphyrin-based conjugated microporous polymer, and the step of providing the polymer comprises: mixing meso-tetra(p-bromophenyl)porphine, p-phenylenediamine, sodium tert-butoxide, 2-(dicyclohexylphosphino)-2,4,6-triisopropylbiphenyl, a catalyst and a third solvent, and reacting at a temperature of 100° C. to 120° C. for 40 hours to 56 hours to obtain the porphyrin-based conjugated microporous polymer; wherein a molar ratio of meso-tetra(p-bromophenyl)porphine, p-phenylenediamine, sodium tert-butoxide, 2-(dicyclohexylphosphino)-2,4,6-triisopropylbiphenyl and the catalyst is 1:(2-5):(4-6):(0.1-0.14):(0.06-0.1).

13. The method according to claim 8, wherein the step of providing the inorganic nanoparticle dispersion solution comprises providing the inorganic nanoparticles and dissolving the inorganic nanoparticles in the second solvent to obtain the inorganic nanoparticle dispersion solution.

14. The method according to claim 13, wherein the inorganic nanoparticles are zinc oxide nanoparticles, and the step of providing the inorganic nanoparticles comprises: mixing a precipitant solution and a zinc salt solution, and reacting at a temperature condition of 50° C. to 70° C. for 2 hours to 3 hours to obtain the zinc oxide nanoparticles, wherein a molar ratio of a precipitant to a zinc salt is (1-2): 6.

15. A light-emitting device comprising a first electrode, a second electrode, an electron transport layer and a light-emitting layer, wherein the first electrode and the second electrode are disposed opposite each other, and the electron transport layer and the light-emitting layer are disposed between the first electrode and the second electrode, wherein a material of the electron transport layer is a composite material, the composite material comprises inorganic nanoparticles and a polymer attached to the inorganic nanoparticles, and the polymer contains a porphyrin group.

16. The light-emitting device according to claim 15, wherein the polymer is a porphyrin-based conjugated microporous polymer, and the porphyrin-based conjugated microporous polymer comprises repeating units, each of the repeating units having a structure represented by formula (I): 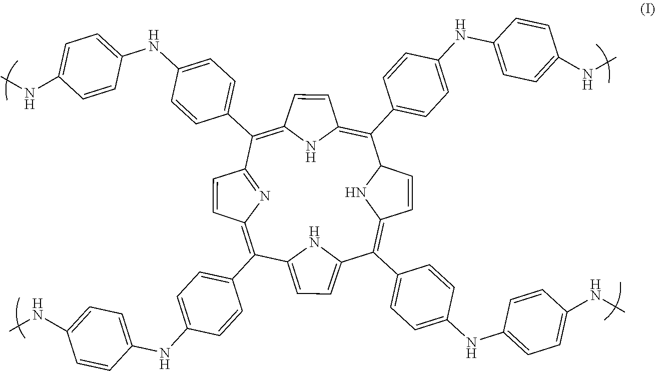
in the porphyrin-based conjugated microporous polymer, a number of the repeating units is n, n ranges from 2 to 10.

17. The light-emitting device according to claim 15, wherein the light-emitting device further comprises a hole transport layer and a hole injection layer;
the first electrode is an anode, the second electrode is a cathode, the light-emitting layer, the hole transport layer, and the hole injection layer are disposed between the electron transport layer and the first electrode, and the light-emitting layer, the hole transport layer, and the hole injection layer are stacked in this order in a direction from the electron transport layer to the first electrode.

18. The light-emitting device according to claim 15, wherein the light-emitting device further comprises the hole transport layer and the hole injection layer; the first electrode is the cathode, the second electrode is the anode, the light-emitting layer, the hole transport layer, and the hole injection layer are disposed between the electron transport layer and the second electrode, and the light-emitting layer, the hole transport layer, and the hole injection layer are stacked in this order in a direction from the electron transport layer to the second electrode.

19. The light-emitting device according to claim 15, wherein a material of the hole transport layer comprises one or more of 4,4′-N,N′-dicarbazolyl-biphenyl, poly[bis(4-phenyl)(2,4,6-trimethylphenyl)amine], N,N′-diphenyl-N,N′-bis(1-naphthyl)-1,1′-biphenyl-4,4″-diamine, N,N′-diphenyl-N,N′-bis(3-methylphenyl)-(1,1′-biphenyl)-4,4′-diamine, poly(N,N′-bis(4-butylphenyl)-N,N′-bis(phenyl)benzidine), N,N′-bis(4-(N,N′-diphenyl-amino)phenyl)-N,N′-diphenylbenzidine, 4,4′,4′-tris(N-carbazolyl)-triphenylamine, 4,4′,4′-tris(N-3-methylphenyl-N-phenylamino)triphenylamine, poly[(9,9′-dioctylfluorene-2,7-diyl)-co-(4,4′-(N-(4-sec-butylphenyl)diphenylamine))], poly(N-vinylcarbazole) and its derivatives, N,N′-bis(1-naphthyl)-N,N′-diphenyl-1,1′-biphenyl-4-4′-diamine, poly(phenylenevinylene), poly[2-methoxy-5-(2-ethylhexyloxy)-1,4-phenylenevinylene], poly[2-methoxy-5-(3′,7′-dimethyloctyloxy)-1,4-phenylenevinylene], 2,2′,7,7′-tetrakis[N,N-bis(4-methoxyphenyl)amino]-9,9′-spirobifluorene, 4,4′-cyclohexylbis[N,N-bis(4-methylphenyl)aniline], 1,3-bis(carbazol-9-yl)benzene, polyaniline, polypyrrole, poly(p-phenylenevinylene), aromatic tertiary amines, polynuclear aromatic tertiary amines, 4,4′-bis(p-carbazol-9-yl)-1,1′-biphenyl compounds, N,N,N′,N′-tetraarylbenzidine, poly(3,4-ethylenedioxythiophene)-polystyrene sulfonic acid and its derivatives, polymethacrylate and its derivatives, poly(9,9-octylfluorene) and its derivatives, polyspirofluorene and its derivatives, polythiophene and its derivatives;
a material of the hole injection layer comprises one or more of poly(3,4-ethylenedioxythiophene)-polystyrenesulfonic acid and its derivatives, copper phthalocyanine, dipyrazino[2,3-f:2′,3′-h]quinoxaline-2,3,6,7,10,11-hexacarbonitrile, polydioxyethyl thiophene, 4,4′,4″-tris(N-3-methylphenyl-N-phenylamino)triphenylamine, tetracyanoquinonedimethane, a transition metal oxide, and a transition metal chalcogenide compound;
the first electrode and the second electrode are independently selected from one of a metal oxide electrode, a doped metal oxide electrode, a composite electrode, a graphene electrode, a carbon nanotube electrode, a metal elemental electrode and an alloy electrode, wherein a material of the metal oxide electrode comprises molybdenum oxide, a material of the doped metal oxide electrode comprises one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide, the composite electrode comprises one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnO, and ZnS/Al/ZnS, and a material of the metal elemental electrode comprises one or more of Ag, Al, Cu, Mo, Au, Pt, Ca, Mg, and Ba; and
a material of the light-emitting layer comprises an organic light-emitting material or a quantum dot light-emitting material; the organic light-emitting material comprises one or more of 4,4′-bis(N-carbazole)-1,1′-biphenyl:tris[2-(p-tolyl)pyridine iridium(III), 4,4′,4″-tris(carbazol-9-yl)triphenylamine:tris[2-(p-tolyl)pyridinate iridium, diarylanthracene derivatives, stilbene aromatic derivatives, pyrene derivatives, fluorene derivatives, 1,4,7,10-tetratert-butylperylene, rubrene derivatives, thermally activated delayed fluorescent materials, exciplex luminescent materials, polyacetylene and its derivatives, polyp-phenylene and its derivatives, polythiophene and its derivatives, and polyfluorene and its derivatives; the quantum dot light-emitting material comprises one or more of a single structure quantum dot and a core-shell structure quantum dot, wherein a material of the single structure quantum dot, a core material of the core-shell structure quantum dot, and a shell material of the core-shell structure quantum dot each comprise one or more of a Group II-VI compound, a Group IV-VI compound, a Group III-V compound, and a Group I-III-VI compound, the Group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe, the Group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe, and the Group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb, the Group I-III-VI compound is selected from one or more of CuInS₂, CuInSe₂, and AgInS₂.

20. The light-emitting device according to claim 19, wherein the first electrode has a thickness of 60 nm to 100 nm, the hole injection layer has a thickness of 10 nm to 50 nm, the hole transport layer has a thickness of 10 nm to 50 nm, the light-emitting layer has a thickness of 20 nm to 60 nm, the electron transport layer has a thickness of 40 nm to 120 nm, and the second electrode has a thickness of 60 nm to 100 nm.
